(19) United States
(12) Patent Application Publication
(10) Pub. No.: US 2025/0218983 A1
(43) Pub. Date: Jul. 3, 2025

(54) MICROELECTRONIC STRUCTURES INCLUDING EMBEDDED INTEGRATED CAPACITOR IN MULTILAYER CORE

(71) Applicant: Intel Corporation, Santa Clara, CA (US)

(72) Inventors: Benjamin Duong, Phoenix, AZ (US); Kari Hernandez, Phoenix, AZ (US); Tolga Acikalin, San Jose, CA (US); Soham Agarwal, Chandler, AZ (US); Jeremy Ecton, Gilbert, AZ (US); Brandon Marin, Gilbert, AZ (US); Pratyush Mishra, Tempe, AZ (US); Pratyasha Mohaptra, Hillsboro, OR (US); Srinivas Pietambaram, Chandler, AZ (US); Marcel Said, Beaverton, OR (US)

(73) Assignee: Intel Corporation, Santa Clara, CA (US)

(21) Appl. No.: 18/400,962

(22) Filed: Dec. 29, 2023

(51) Int. Cl. H01L 23/64; H01L 21/48; H01L 23/00; H01L 23/498

(52) U.S. Cl. CPC H01L 23/642; H01L 21/4857; H01L 23/49822; H01L 23/49838; H01L 24/16; H01L 2224/16227; H01L 2924/19041; H01L 2924/19103

(57) ABSTRACT

Microelectronic integrated circuit package structures include one or more trench capacitors extending through a portion a device structure. The device structure is embedded within a portion of a core layer of a multi core package substrate, wherein one or more conductive interconnect structures are coupled with the one or more trench capacitors. A thickness of the device structure is equal to a thickness of the core layer.

### BACKGROUND

In electronics manufacturing, integrated circuit (IC) packaging is a stage of manufacture where an IC that has been fabricated on a die or chip comprising a semiconducting material is coupled to a supporting case or “package” that can protect the IC from physical damage and support electrical interconnect suitable for further connecting to a host component, such as a printed circuit board (PCB). In the IC industry, the process of fabricating a package is often referred to as packaging, or assembly.

Some package architectures may include embedded passive devices, such as deep trench capacitors (DTC) s which may be embedded into a package substrate core. In some cases, a DTC may be fabricated using silicon technology, where a thickness of the DTC is limited to a thickness of a silicon wafer as well as by silicon processing limitations. This thickness limitation can become an issue for a core with a thickness that is greater than 600 microns. Such an embedded silicon based DTC is prone to shifting or rotation within the cavity of the core during and after encapsulation within the core. For example, a thin DTC which is limited to about a 600 micron thickness, when embedded into a core with a thickness that is greater than 600 microns will result in a thickness mismatch between the DTC and the substrate core. This thickness mismatch can lead to significant yield, reliability, and manufacturability challenges. In addition, voiding may occur a result of insufficient filling of encapsulant material as well as vertical and tilt misalignment during embedding.

### BRIEF DESCRIPTION OF THE DRAWINGS

The subject matter described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements. In the figures:

FIGS. 1A-1C are cross-sectional views of IC package structures comprising an embedded IC device, in accordance with some embodiments.

FIGS. 2A-2E are cross-sectional views of IC package structures comprising an embedded IC device, in accordance with some embodiments.

FIGS. 3A-3F are cross-sectional views of IC package structures comprising an embedded IC device, in accordance with some embodiments.

FIGS. 4A-4E are cross-sectional views of an IC package structures comprising an embedded IC device, in accordance with some embodiments.

FIG. 5 is a cross-sectional view of an IC package structures comprising an embedded IC device, in accordance with some embodiments.

FIG. 6 illustrates a flow chart of processes for the fabrication of IC package structures having an embedded IC device, in accordance with some embodiments.

FIG. 7 is a functional block diagram of an electronic computing device, in accordance with some embodiments of the present disclosure.

### DETAILED DESCRIPTION

Embodiments are described with reference to the enclosed figures. While specific configurations and arrangements are depicted and discussed in detail, it should be understood that this is done for illustrative purposes only. Persons skilled in the relevant art will recognize that other configurations and arrangements are possible without departing from the spirit and scope of the description. It will be apparent to those skilled in the relevant art that techniques and/or arrangements described herein may be employed in a variety of other systems and applications other than what is described in detail herein.

Reference is made in the following detailed description to the accompanying drawings, which form a part hereof and illustrate exemplary embodiments. Further, it is to be understood that other embodiments may be utilized and structural and/or logical changes may be made without departing from the scope of claimed subject matter. It should also be noted that directions and references, for example, up, down, top, bottom, and so on, may be used merely to facilitate the description of features in the drawings. Therefore, the following detailed description is not to be taken in a limiting sense and the scope of claimed subject matter is defined solely by the appended claims and their equivalents.

In the following description, numerous details are set forth. However, it will be apparent to one skilled in the art, that embodiments may be practiced without these specific details. In some instances, well-known methods and devices are shown in block diagram form, rather than in detail, to avoid obscuring the embodiments. Reference throughout this specification to “an embodiment” or “one embodiment” or “some embodiments” means that a particular feature, structure, function, or characteristic described in connection with the embodiment is included in at least one embodiment. Thus, the appearances of the phrase “in an embodiment” or “in one embodiment” or “some embodiments” in various places throughout this specification are not necessarily referring to the same embodiment. Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

As used in the description and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items.

The terms “coupled” and “connected,” along with their derivatives, may be used herein to describe functional or structural relationships between components. It should be understood that these terms are not intended as synonyms for each other. Rather, in particular embodiments, “connected” may be used to indicate that two or more elements are in direct physical, optical, or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause and effect relationship).

The terms “over,” “under,” “between,” and “on” as used herein refer to a relative position of one component or material with respect to other components or materials where such physical relationships are noteworthy. For example in the context of materials, one material or layer over or under another may be directly in contact or may have one or more intervening materials or layers. Moreover, one material between two materials or layers may be directly in contact with the two materials/layers or may have one or more intervening materials/layers. In contrast, a first material or layer “on” a second material or layer is in direct physical contact with that second material/layer. Similar distinctions are to be made in the context of component assemblies.

As used throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C.

Unless otherwise specified in the explicit context of use, the term “predominantly” means more than 50%, or more than half. For example, a composition that is predominantly a first constituent means more than half of the composition is the first constituent (e.g., <50 at. %). The term “primarily” means the most, or greatest, part. For example, a composition that is primarily a first constituent means the composition has more of the first constituent than any other constituent.

The term “package” generally refers to a self-contained carrier of one or more dice, where the dice are attached to the package substrate, and may be encapsulated for protection, with integrated or wire-bonded interconnects between the dice and leads, pins or bumps located on the external portions of the package substrate. The package may contain a single die, or multiple dice, providing a specific function. The package is usually mounted on a printed circuit board for interconnection with other packaged integrated circuits and discrete components, forming a larger circuit.

The term “dielectric” generally refers to any number of non-electrically conductive materials that make up the structure of a package substrate.

The term “metallization” generally refers to metal layers formed over and through the dielectric material of the package substrate. The metal layers are generally patterned to form metal structures such as traces and bond pads. The metallization of a package substrate may be confined to a single layer or in multiple layers separated by layers of dielectric.

The term “bond pad” generally refers to metallization structures that terminate integrated traces and vias in integrated circuit packages and dies. The term “solder pad” may be occasionally substituted for “bond pad” and carries the same meaning.

The term “solder bump” generally refers to a solder layer formed on a bond pad. The solder layer typically has a round shape, hence the term “solder bump”.

The term “substrate” generally refers to a planar platform comprising dielectric and metallization structures. The substrate mechanically supports and electrically couples one or more IC dies on a single platform, with encapsulation of the one or more IC dies by a moldable dielectric material. The substrate generally comprises solder bumps as bonding interconnects on both sides. One side of the substrate, generally referred to as the “die side”, comprises solder bumps for chip or die bonding. The opposite side of the substrate, generally referred to as the “land side”, comprises solder bumps for bonding the package to a printed circuit board.

The vertical orientation is in the z-direction and it is understood that recitations of “top”, “bottom”, “above” and “below” refer to relative positions in the z-dimension with the usual meaning. However, it is understood that embodiments are not necessarily limited to the orientations or configurations illustrated in the figure.

The terms “substantially,” “close,” “approximately,” “near,” and “about,” generally refer to being within +/−10% of a target value (unless specifically specified). Unless otherwise specified the use of the ordinal adjectives “first,” “second,” and “third,” etc., to describe a common object, merely indicate that different instances of like objects to which are being referred and are not intended to imply that the objects so described must be in a given sequence, either temporally, spatially, in ranking or in any other manner.

Views labeled “cross-sectional”, “profile” and “plan” correspond to orthogonal planes within a Cartesian coordinate system. Thus, cross-sectional and profile views are taken in the x-z plane, and plan views are taken in the x-y plane. Typically, profile views in the x-z plane are cross-sectional views. Where appropriate, drawings are labeled with axes to indicate the orientation of the figure.

Embodiments discussed herein address problems associated with packaging architectures and methods of embedding passive devices, such as deep trench capacitors (DTC)'s into a package substrate. Embedding capacitors into a substrate core, for example enables the achievement of a fully integrated voltage regulator (FIVR). The embodiments herein include fabricating device structures, such as DTCs and embedding them within one or more core layers of a multicore package structure, wherein a thickness of core layers is matched with a thickness of the embedded device structure. A primary benefit includes the ability to precisely target a final DTC device thickness to correspond with a core layer thickness. DTC thicknesses can be easily tailored to different products and a desired embedding core layer. The embodiments herein allow for the embedding of DTCs into thick overall core structures as well as providing for additional routing layers between multiple core layers.

Embodiments describe methods of fabricating a multi core package substrate having one or more device structures embedded within one or more core layers of the package substrate. In an embodiment, the device structures comprise one or more trenches extending within a first portion. A metal/insulator/metal film stack is formed within individual trenches to form a DTC. A second portion of the device structure is below the first portion, wherein the second portion is free of the one or more trenches.

The device structures may then be embedded within a core layer of a package substrate. An electrical routing structure comprising a redistribution layer (RDL) metallization in some embodiments may be built-up on at least one side of the core portion, and integrated circuit (IC) die(s) may be assembled to interconnect with the routing structure.

The embodiments herein enable a cost-efficient process that can prevent shifting or rotation of DTCs within a multi core package substrate, as well as enabling matching between a thickness of a core layer and a thickness of a DTC.

The architecture described herein may be assembled and/or fabricated with one or more of the features or attributes provided in accordance with various embodiments. A number of different assembly and/or fabrication methods may be practiced to enable passive structures comprising, such as DTC's to be reliably embedded within a package structure, according to one or more of the features or attributes described herein.

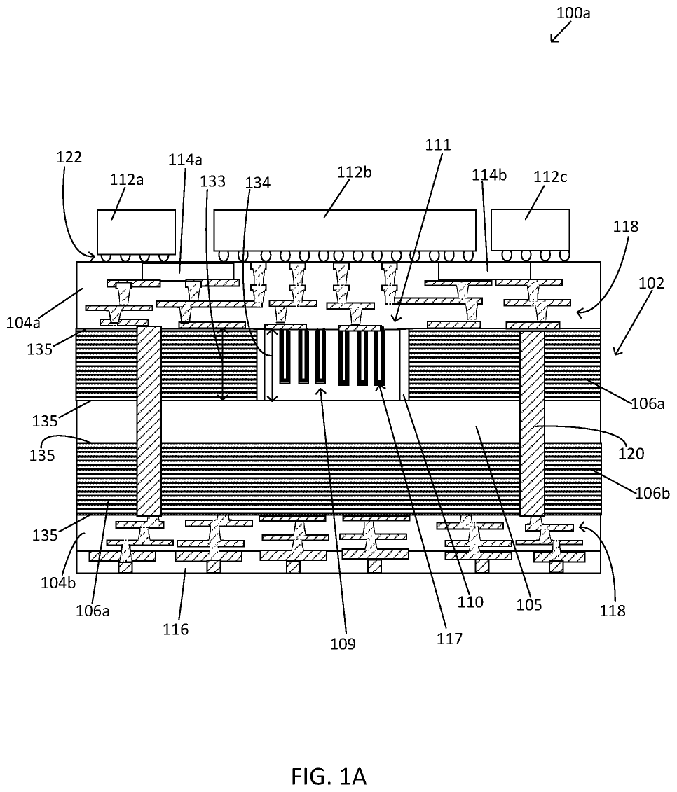

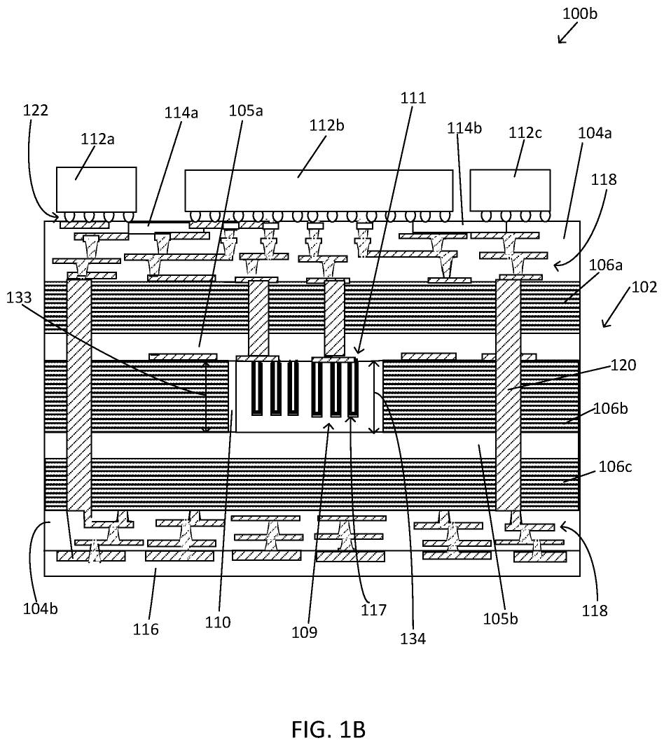

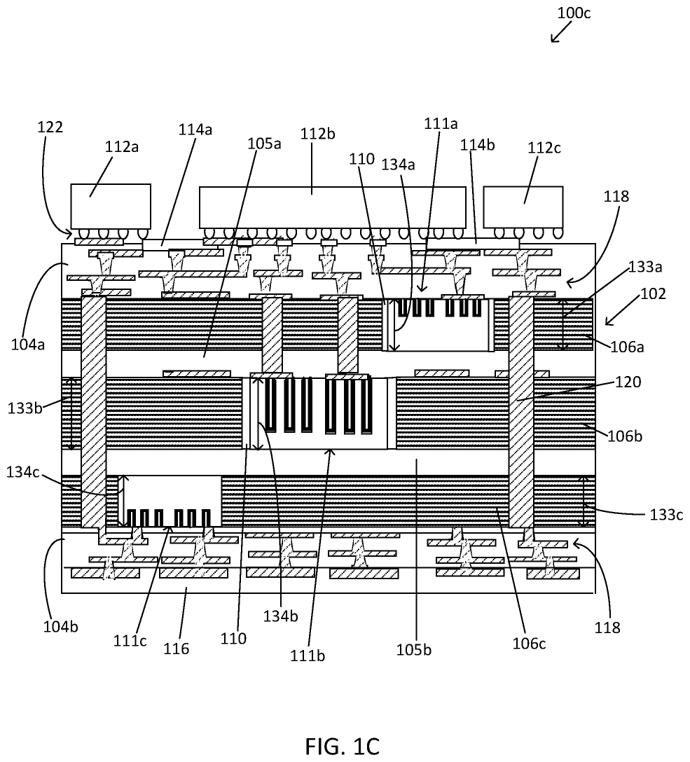

FIGS. 1A-1C illustrate embodiments of package structures including embedded passive devices, such as DTC's. The package structures are formed utilizing standard deposition and lithographic processing techniques. The methods of fabrication described herein create improved device performance in advanced 2.5D and 3D packaging.

FIG. 1A is a cross-sectional view of a portion of integrated circuit (IC) package structure 100a, in accordance with some embodiments. As shown, a package substrate 102 comprises core layers 106a, 106b, wherein the core layers 106a, 106b comprise a rigid material, such as epoxy resin or fiberglass-reinforced laminate. The core layers 106a, 106b provide mechanical strength and stability to the package substrate 102. In an embodiment, core layers, such a core layers 106a, 106b, may each be plated with a conductive material such as a copper foil layer 135 on top and/or bottom surfaces of individual core layers 106a, 10b. In an embodiment, the core layers 106a, 106b and 106c comprise core layers of a multi-layer core structure. Build up layers 104a, 104b may be on surfaces of the core layers 106a, 106b respectively and may comprise multiple layers of insulating materials and conductive traces that are built on top of the core layers 106a, 106b using a sequential build-up process, for example. A prepreg material 105, (which may comprise impregnated resin material which encases a weave material) is between the core layers 106a, 106b in an embodiment. The prepreg material 105 may comprise a non-rigid laminate material with between 30 to about 80 percent resin material by weight, in an embodiment.

A device structure 111 is embedded within an outer core layer 106a, wherein a thickness 134 of the device structure 111 is substantially the same as a thickness 133 of the core layer 106a. In an embodiment, the device structure 111 may comprise a silicon material. In an embodiment the device structure 111 may comprise a solid layer of silicon rectangular in shape in plan view. One or more trenches 109 are within a portion of the device structure 111, and may be filled with a film stack 117, such as a metal/insulator/metal film stack, for example. In an embodiment, the film stack 117 may comprise a first conductive material, such as copper, on a trench 109 sidewall, a dielectric material on the first conductive material, and a second conductive material on the dielectric material.

In an embodiment, the device structure 111 including the one or more trenches 109 filled with the film stack 117 comprises a deep trench capacitor (DTC) 111. Since the surfaces of the DTC 111 are coplanar with the surfaces of the core layer 106a, the DTC 111 does not shift or rotate within the package substrate 102. In an embodiment, a thickness of the DTC 111 may be less than about 800 microns.

An encapsulant material 110 is between the DTC 111 and the core layer 106a. The encapsulant comprises any suitable dielectric or epoxy material, such as a molding material for example. In an embodiment, one or more embedded interconnect bridge structures 114a, 114b may be embedded within the build up layer 104a. The embedded interconnect bridge structures 114a, 114b may provide interconnect coupling structures between die, such as die 112a, 112b and 112c. Conductive solder balls 122 couple the die 112a, 112b and 112c to the package substrate 102. Solder balls 122 may comprise any suitable solder ball structures such as silver, gold, tin or copper materials, or combinations thereof, for example.

Conductive trace layers 118 may be distributed within the build up layers 104a, 104b. Conductive via structures 120 extend through the package substrate 102 to couple the package substrate 102 to devices within and on the package substrate 102. The conductive via structures 120 and conductive traces 118 may comprise a copper material or copper alloys, in an embodiment, but may comprise any suitable conductive material. The conductive via structures 120 and conductive traces 118 form an interconnect path with which to conductively couple any devices coupled within or to the package structure 100. A layer 116, such as a silicon nitride material or a solder material, for example, may be on a side of the package substrate opposite the die 112a, 112b and 112c.

FIG. 1B is a cross-sectional view of a portion of integrated circuit (IC) package structure 100b in accordance with some embodiments. As shown, a package substrate 102 comprises core layers 106a, 106b, 106c. The core layers 106a, 106b, 106c provide mechanical strength and stability to the package substrate 102. Build up layers 104a, 104b may be on surfaces of the core layers 106a, 106c respectively and may comprise multiple layers of insulating materials and conductive traces that are built on top of the core layers 106a, 106c using a sequential build-up process, for example. Prepreg material 105a is between the core layers 106a, 106b and prepreg material 105b is between the core layers 106b, 106c in an embodiment.

A device structure 111 is embedded within the inner core layer 106b, wherein a thickness 134 of the device structure 111 is substantially the same as a thickness 133 of the core layer 106b. In an embodiment, the device structure 111 may comprise a silicon material. In an embodiment the device structure 111 may comprise a solid layer of silicon rectangular in shape in plan view. In an embodiment, the one or more trenches 109 filled with the film stack 117 comprise a deep trench capacitor structure within the (DTC) 111. Since the surfaces of the DTC 111 are coplanar with the surfaces of the core layer 106b, the DTC 111 does not shift or rotate within the package substrate 102. In an embodiment, a thickness of the DTC 111 may be less than about 800 microns.

An encapsulant material 110 is between the DTC 111 and the core layer 106b. In an embodiment, one or more embedded interconnect bridge structures 114a, 114b may be embedded within the build up layer 104a. The embedded interconnect bridge structures 114a, 114b may provide interconnect coupling structures between die, such as die 112a, 112b and 112c. Conductive solder balls 122 couple the die 112a, 112b and 112c to the package substrate 102. Solder balls 122 may comprise any suitable solder ball structures such as silver, gold, tin or copper materials, or combinations thereof, for example.

Conductive trace layers 118 may be distributed within the build up layers 104a, 104b. Conductive via structures 120 extend through the package substrate 102 to couple the package substrate 102 to devices within and on the package substrate 102. A passivation layer 116, such as a silicon nitride material for example, may be on a side of the package substrate opposite the die 112a, 112b and 112c.

FIG. 1C is a cross-sectional view of a portion of integrated circuit (IC) package structure 100c, in accordance with some embodiments. As shown, a package substrate 102 comprises core layers 106a, 106b, 106c. Build up layers 104a, 104b may be on surfaces of the core layers 106a, 106c respectively and may comprise multiple layers of insulating materials and conductive traces that are built on top of the core layers 106a, 106c using a sequential build-up process, for example. Prepreg material 105a is between the core layers 106a, 106b and prepreg material 105b is between the core layers 106b, 106c in an embodiment.

A first device structure 111a is embedded within an outer core layer 106a, wherein a thickness 134a of the device structure 111a is substantially the same as a thickness 133a of the core layer 106a. In an embodiment, the device structure 111a may comprise a silicon material. In an embodiment the device structure 111a may comprise a deep trench capacitor (DTC) 111a. Since the surfaces of the DTC 111a are coplanar with the surfaces of the core layer 106a, the DTC 111a does not shift or rotate within the package substrate 102. In an embodiment, the thickness 134a of the DTC 111a may be less than about 800 microns. An encapsulant material 110 is between the DTC 111a and the core layer 106a.

A second device structure 111b is embedded within an inner core layer 106b, wherein a thickness 134b of the device structure 111b is substantially the same as a thickness 133b of the core layer 106b. In an embodiment, the device structure 111b may comprise a silicon material. In an embodiment the device structure 111b may comprise a deep trench capacitor (DTC) 111b. Since the surfaces of the DTC 111b are coplanar with the surfaces of the core layer 106b the DTC 111b does not shift or rotate within the package substrate 102. In an embodiment, the thickness 134b of the DTC 111b may be less than about 800 microns. An encapsulant material 110 is between the DTC 111b and the core layer 106b. In an embodiment, the core layers 106a, 106b may comprise the same thicknesses, but in other embodiments the thicknesses may be different from each other.

In an embodiment, a third device structure 111c is embedded within the core layer 106c, wherein a thickness 134c of the device structure 111c is substantially the same as a thickness 133c of the core layer 106c. In an embodiment, the device structure 111c may comprise a silicon material. In an embodiment the device structure 111c may comprise a deep trench capacitor (DTC) 111c. Since the surfaces of the DTC 111c are coplanar with the surfaces of the core layer 106c, the DTC 111c does not shift or rotate within the package substrate 102. In an embodiment, any number of DTCs may be embedded within any core layers of a multilayer core package structure.

In an embodiment, one or more embedded interconnect bridge structures 114a, 114b may be embedded within the build up layer 104a. The embedded interconnect bridge structures 114a, 114b may provide interconnect coupling structures between die, such as die 112a, 112b and 112c. Conductive solder balls 122 couple the die 112a, 112b and 112c to the package substrate 102. Solder balls 122 may comprise any suitable solder ball structures such as silver, gold, tin or copper materials, or combinations thereof, for example.

Conductive trace layers 118 may be distributed within the build up layers 104a, 104b. Conductive via structures 120 extend through the package substrate 102 to couple the package structure 102 to devices within and on the package structure 100c. A passivation layer 116, such as a silicon nitride material for example, may be on a side of the package substrate opposite the die 112a, 112b and 112c.

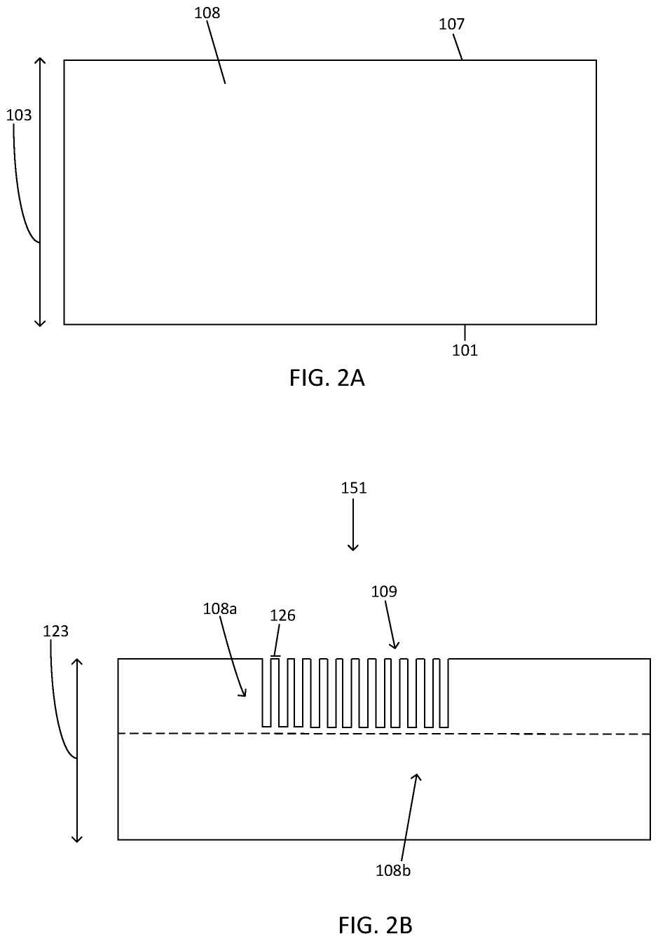

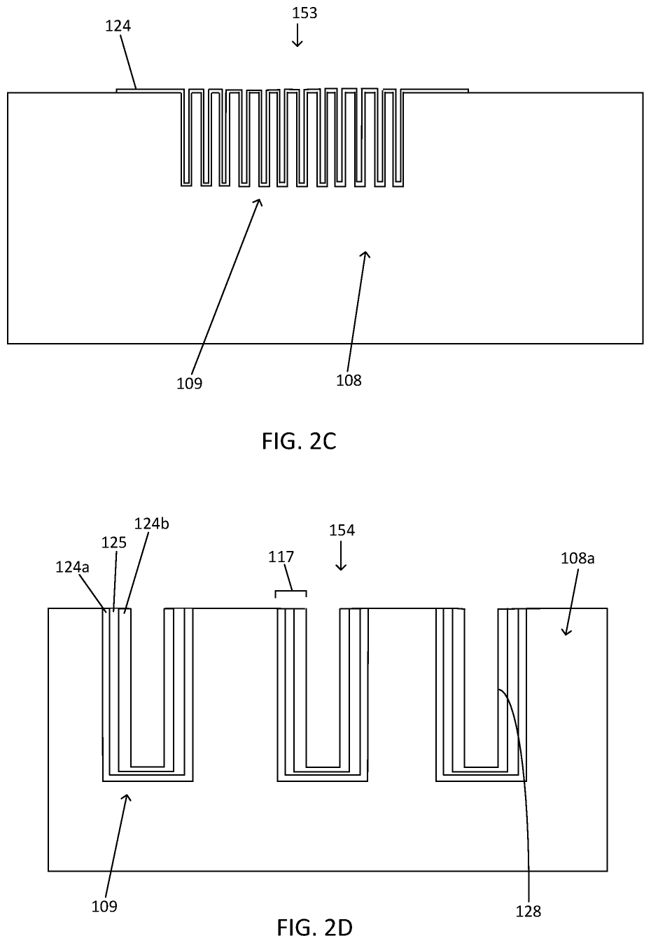

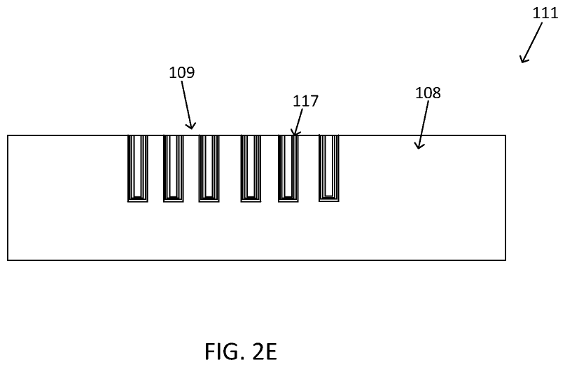

FIGS. 2A-2E illustrate embodiments of forming IC package structures (such as the IC package structures of (FIGS. 1A-1C), for example. FIG. 2A depicts a cross-sectional view of a portion of a substrate 108 according to some embodiments. As shown, the substrate 108 may comprise a device substrate 108. IC device package structures may be fabricated upon device substrate 108. Device substrate 108 may comprise a silicon material, such as a silicon wafer material that may have been previously formed into any shape in plan view (e.g., x-y plane) suitable for a packaging workpiece, such as rectangular shape. Device substrate 108 may comprises a thickness 103 which may be optimized according to particular design requirements, for example to limit warpage. In exemplary embodiments, the thickness 103 may comprise below about 800 microns. Device substrate 108 may comprise a first side 101 and a second side 107.

In FIG. 2B, a process 151 may be employed to form one or more trenches 109 within and through a first portion 108a of the device substrate 108. A second portion 108b is free of the one or more trenches 109 in an embodiment. Process 151 may comprise such processes as a wet or dry etch process, or a laser assisted process. In an embodiment, any process known to be suitable for forming trenches in bulk silicon may be utilized, such as a reactive ion etch process, for example. In some embodiments, a laser ablation process or any other such techniques known to be suitable for forming features through a thickness of the device substrate 108 may be employed to achieve a desired diameter and feature pitch of the one or more trenches 109 within the first portion 108a of the device substrate 108.

In an embodiment, the first portion 108a of the device substrate 108 may comprise less than about 50 percent of a post etch thickness 123 of the device substrate 108. In another embodiment, the first portion 108a of the device substrate 108 may comprise less than about 35 percent of a post etch thickness 123 of the device substrate. The post etch thickness 123 of the device substrate 108 may comprise a target thickness according to the placement of the device substrate 108 within a package substrate such as within a core portion of the package substrate. For example, the post etch thickness 123 may be targeted to be substantially equal to a package core thickness. In an embodiment, a pitch 126 between individual ones of the one or more trenches 109 may comprise between about 1 micron and 10 microns but may be optimized depending upon the particular application.

In FIG. 2C, a process 153 may be employed to form a conductive material 124 within the one or more trenches 109. The process 153 may comprise any suitable process, such as a physical deposition process, such as a plasma vapor deposition (PVD) process for example, or a chemical vapor deposition (CVD) or atomic layer deposition (ALD) process, followed by a patterning process. The conductive material 124 may comprise a copper material 124 or copper alloys, in an embodiment, but may comprise any suitable conductive material. In an embodiment, the conductive material 124 may comprise a polysilicon material or any other low resistivity metal for Vss and Vdd electrodes, while iridium/IrO2 or ruthenium/RuO2, may be used for contact metals.

The conductive material 124 forms an interconnect path with which to conductively couple to any devices within or on a package structure. The conductive material 124 may comprise a portion of a passive device formed within the device substrate 108, such as a deep trench capacitor or an inductor, for example.

FIG. 2D depicts a section of the first portion 108a of the device substrate 108 wherein a film stack 117 comprising a metal/insulator/metal (MIM) film stack may be formed using formation process 154 within the one or more trenches 109. In an embodiment, the process 154 may comprise such processes as chemical vapor deposition (CVD) or physical vapor deposition (PVD), for example. In an embodiment, a first conductive material 124a may be formed on a sidewall 128 of the one or more trenches 109 wherein the sidewall 128 may comprise a sidewall of the device substrate 108.

In an embodiment, the first conductive material 124a may comprise copper or a copper alloy but may comprise any suitable conductive material. In an embodiment, a dielectric material 125 may be formed on the conductive material. The dielectric material 125 may comprise a silicon oxide or a silicon nitride material, in an embodiment, but may comprise any suitable dielectric material, such as TiO2, HfO2, HZO, or combinations thereof. A second conductive material 124b may be formed on the dielectric material 125, wherein the second conductive material 124b may comprise the same or a different conductive material as the first conductive material 124a. In an embodiment, any suitable combinations of film layers/materials may be formed within the one or more trench openings utilizing process 154, such as an inductor film stack.

FIG. 2E depicts a deep trench capacitor (DTC) structure 111 comprising one or more trenches 109 within the device substrate 108. The one or more trenches 109 comprise a film stack 117 comprising a metal/insulator/metal (MIM) film stack which are to be conductively coupled to conductive traces/via structures within a package structure such as any of the package structures of FIGS. 1A-1C, for example.

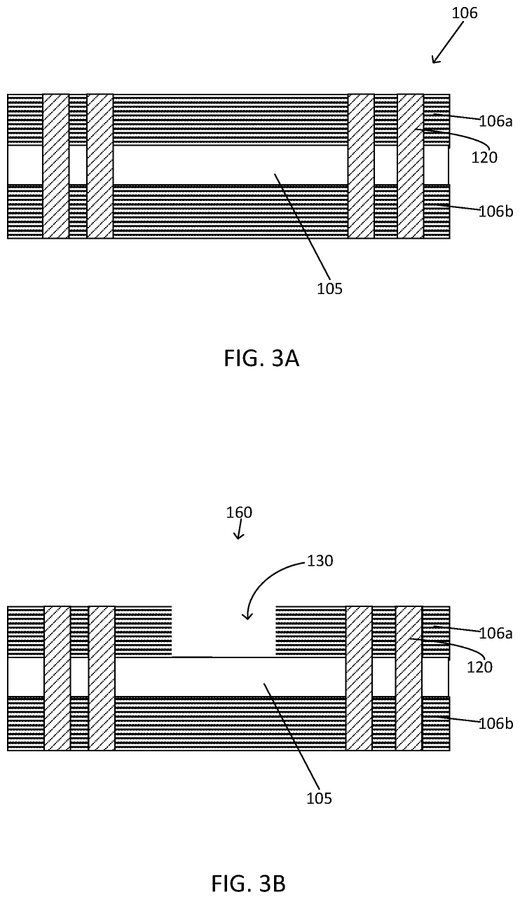

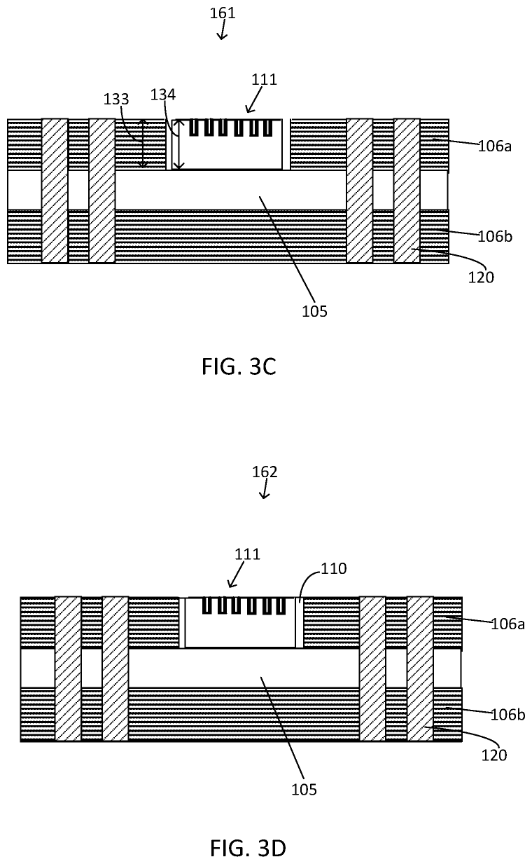

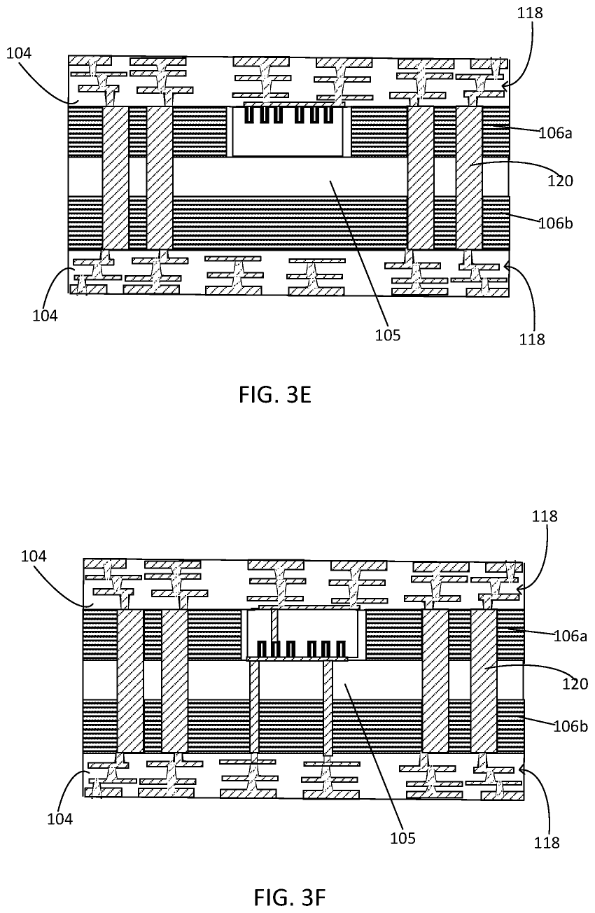

FIGS. 3A-3E depict a method of placing a passive device, such as a DTC, within an outer layer of a multi-layer core stack. FIG. 3A depicts a portion of a multi-layer package core 106 with conductive via structures 120 extending through the multi-layer package core 106. A first core layer 106a is on a prepreg material 105. In an embodiment, the prepreg material 105 may comprise an insulator material such as fiberglass weave and resin materials. In an embodiment, the core layers 106 may comprise an FR-4 (Flame Retardant) mix of elements, including titanium epoxy laminates and traces of copper. The core layers 106a, 106b may comprise a rigid surface coated on either side with copper, in an embodiment. Although two core layers are shown, any number of core layers 106 may be stacked on each other and separated by a prepreg layer 105, depending upon the particular application.

In FIG. 3B, a process 160 removes a portion of the core layer 106a. The process 160 may include any suitable etching or drilling process to remove the portion of the core 106a to form a core cavity 130. In an embodiment, the cavity 130 can be formed in core layer 106a before stacking the core layers 106 upon one another. In FIG. 3C, a device structure 111 such as a DTC 111 according to embodiments herein, is placed within the core cavity 130 using a placement process 161 such as a pick and place process 161. A thickness 133 of the core layer 106a is substantially the same as a thickness 134 of the DTC 111, such that the DTC and core layer 106a are substantially coplanar with each other.

In FIG. 3D, an encapsulation process 162 may be employed wherein an encapsulant material 110 may be formed within the space between the core 106a and the DTC. The encapsulant material 110, may comprise materials such as a mold material, a standard Ajinomoto Build-Up Film (ABF), or a photo imageable dielectric material, for example. In FIG. 3E, build up material 104 including conductive via structures 120 may be formed on the core layers 106a, 106b, wherein the DTC 111 is conductively coupled to the conductive via structures 120. In an embodiment, multiple cores and pre-preg layers may be stacked together according to particular design requirements.

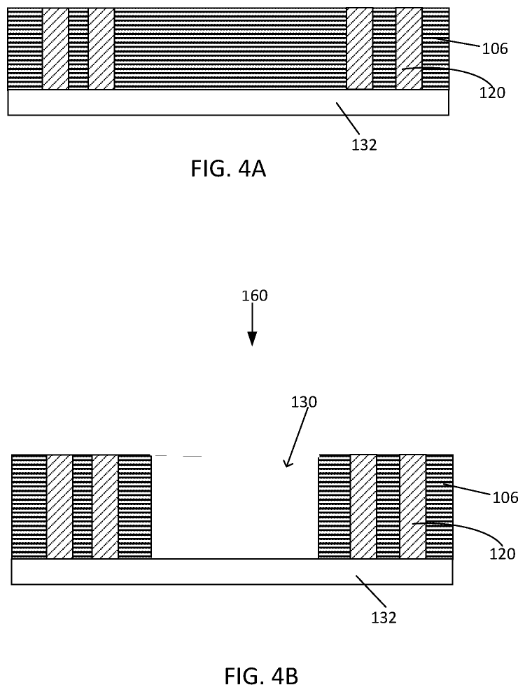

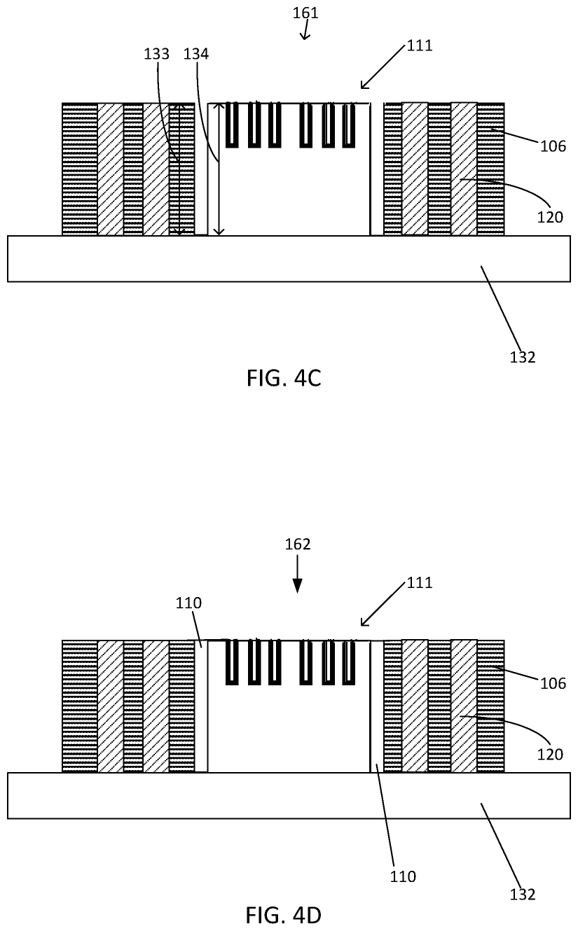

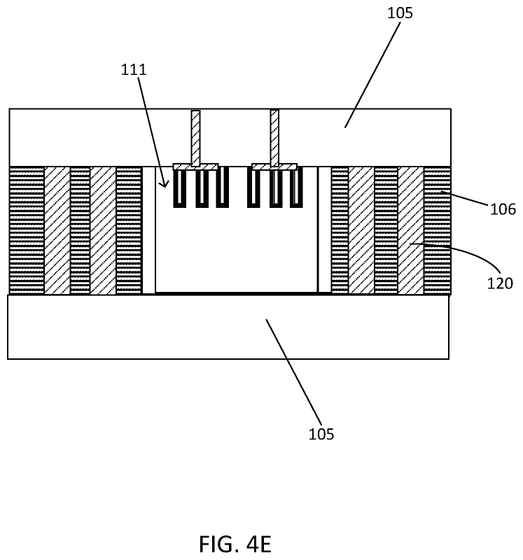

FIGS. 4A-4E depict a method of placing a passive device, such as a DTC, within an inner layer of a multi-layer core stack. FIG. 4A depicts a portion of a multi-layer package core 106 with conductive via structures 120 extending through the core 106. The core 106 is fabricated to match a thickness of a DTC to be subsequently placed within the core. The core 106 may be on a carrier 132, which may comprise such materials as silicon, glass or ceramic materials, for example. In FIG. 4B, a process 160 removes a portion of the core 106 to form a cavity 130. In FIG. 4C, a device structure 111 such as a DTC 111 according to embodiments herein, is placed within the core cavity 130 using a placement process 161 such as a pick and place process 161. A thickness 133 of the core layer 106 is substantially the same as a thickness 134 of the DTC 111, such that the DTC and core layer 106 are substantially coplanar with each other.

In FIG. 4D, an encapsulation process 162 may be employed wherein an encapsulant material 110 may be formed within the space between the core 106a and the DTC. The encapsulant material 110, such as a mold material, a standard Ajinomoto Build-Up Film (ABF), or a photo imageable dielectric material, for example. In FIG. 4E, the carrier 132 may be removed and prepreg material 105 may be formed on the core layer 106. In an embodiment, multiple cores and pre-preg layers may be stacked together according to particular design requirements.

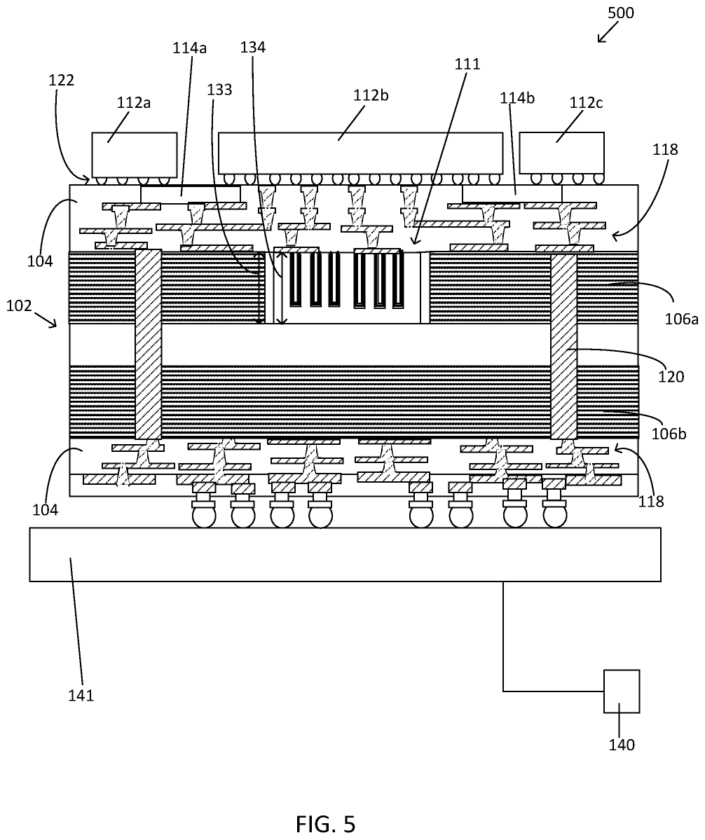

FIG. 5 depicts an IC multi core package structure 500, wherein dies 112a, 112b and 112c are on a package substrate 102, such as a package substrate 100 of FIG. 1A, for example. In some embodiments, the dies 112a, 112b and 112c may comprise chiplet structures 112a, 112b and 112c which may comprise components of a system on a chip (SOC) structure. The dies 112a, 112b and 112c are coupled to each other and to a device structure 111 such as a DTC 111, according to any of the embodiments disclosed herein, through a redistribution layer (RDL) metallization 118. The device 111 is embedded in a core layer 106a, wherein a thickness 133 of the core layer 106a is substantially the same as a thickness 134 of the DTC 111, such that the DTC 111 and core layer 106a are substantially coplanar with each other.

Any number of die/devices may be coupled to the substrate 102. The substrate 102 may be coupled to a board 141, such as a printed circuit board, in an embodiment. Conductive bumps 122 may comprise any conductive element for coupling to an outside die or other device. In an embodiment, the conductive bumps 122 may include silver, tin, or copper, or combinations or alloys thereof. Conductive vias 120 extend through the core layers 106a, 106b and build up material 104 to couple with the board 141. A power supply 140, which may comprise any suitable power supply as known in the art, may be coupled to dies 112a, 112b and 112c via IC package substrate 102, in an embodiment.

Discussion now turns to operations for assembling and/or fabricating the discussed structures.

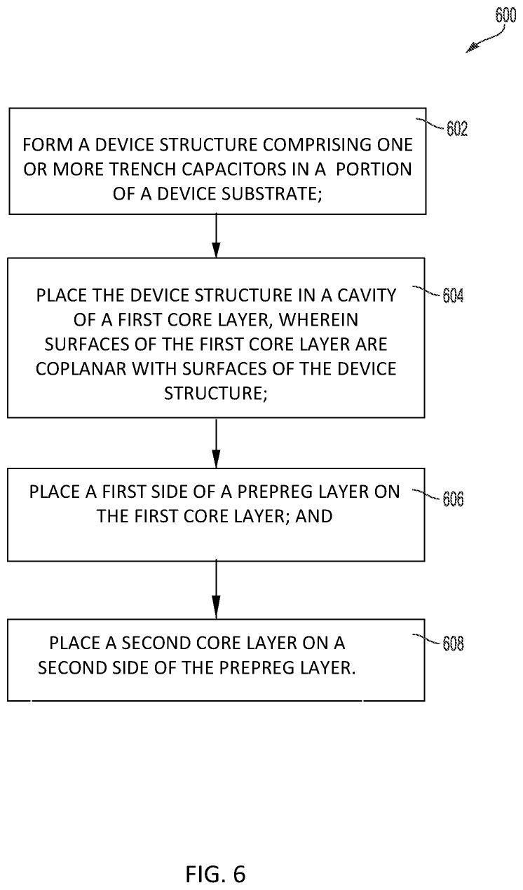

FIG. 6 is a flow chart of a process 600 of fabricating package structures according to some embodiments. For example, process 600 may be used to fabricate any of the microelectronic IC package structures of FIGS. 2A-2E.

As set forth in block 602, one or more trench capacitors are formed in a first portion of a device substrate to form a device structure. In an embodiment, the device substrate may comprise a silicon material. In an embodiment, the device substrate may comprise any suitable material. The device substrate may be a solid bulk material layer that may have been previously formed into any shape in plan view (e.g., x-y plane) suitable for a packaging workpiece, such as rectangular. In an embodiment, the device substrate has a thickness that may vary with implementation, for example to limit warpage. In an embodiment, a thickness of the device substrate is advantageously below about 800 microns.

In an embodiment, the device substrate may be thinned utilizing any appropriate etching process, such as a laser assisted process or a wet or dry etch process, for example. The device substrate may be thinned to a target thickness, which may be determined with respect to the core layer where the device s is to be placed. For example, in an embodiment, the device structure is to be placed within a core layer of a multi core substrate package so that the device substrate may be thinned to a thickness of the core layer, and/or the core layer may be fabricated such that a thickness of the device structure is substantially the same as a thickness of the substrate core layer.

In an embodiment, a thickness of a first portion of the device substrate may comprise less than about 50 percent of a total thickness of the device substrate. In another embodiment, the thickness of the first portion the device substrate may comprise less than about 30 percent of the thickness of the device substrate. In an embodiment a second portion of the device substrate is free of the one or more trenches. In an embodiment, the one or more trenches may be formed by utilizing any appropriate etching process, such as a wet or dry etch process, for example. In an embodiment, the one or more trenches may comprise about a 40:1 aspect ratio, and a pitch of about 1 micron to about 10 microns between individual ones of the one or more trenches. In other embodiments, the one or more trenches may comprise greater than about 10:1 aspect ratio. In an embodiment, the one or more trenches may be formed simultaneously with a thinning process of the device substrate.

A conductive layer may be formed on a sidewall of the one or more trenches formed within the device substrate. In an embodiment, a first conductive layer may be formed within the one or more trenches and may comprise copper or copper alloy materials. The first conductive material may be formed using any suitable formation process, such as a physical deposition process, for example. In an embodiment, a dielectric material may be formed on the first conductive material within the one or more trenches. The dielectric material may comprise any suitable dielectric material such as a silicon dioxide or a silicon nitride material for example.

Subsequently, a second conductive material may be formed on the dielectric material, such that a metal/insulator/metal (MIM) structure may be formed within individual trenches of the one or more trenches to form the device structure. The MIM structure may comprise a trench capacitor structure with electrical contacts to electrically couple to a package substrate. In other embodiments, passive device structures such as a DTC or an inductor may be formed within the one or more trenches depending upon the particular application requirements.

At step 604, the device structure, such as a DTC may be placed in a cavity of a first core layer of a multilayer core stack of a package substrate. The package substrate may comprise any number of core layers. Surfaces of the first core layer and surfaces of the device structure are coplanar with each other.

At step 606, a first side of a prepreg layer may be formed/placed on the first core layer. The prepreg layer may comprise a build up layer with conductive traces within the prepreg layer. At step 608, a second core layer may be formed/placed on a second side of the prepreg layer. In an embodiment, any number of core layers may be stacked upon each other separated by prepreg and/or build up layers as required by the particular application. In an embodiment, any number of DTCs may be placed within a multi-layer core package, wherein the thickness of the DTC matches a thickness of the core layer into which it is placed. In an embodiment, multiple DTCs may be placed within the same core layer.

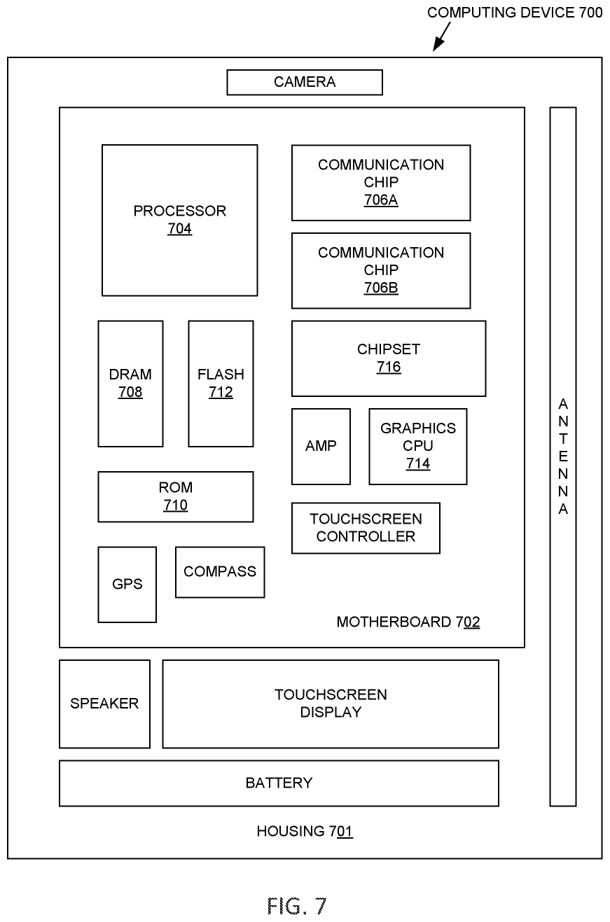

FIG. 7 illustrates an electronic or computing device 700 in accordance with one or more implementations of the present description. The computing device 700 may include a housing 701 having a board 702 disposed therein. The computing device 700 may include a number of integrated circuit components, including but not limited to a processor 704, at least one communication chip 706A, 706B, volatile memory 708 (e.g., DRAM), non-volatile memory 710 (e.g., ROM), flash memory 712, a graphics processor or CPU 714, a digital signal processor (not shown), a crypto processor (not shown), a chipset 716, an antenna, a display (touchscreen display), a touchscreen controller, a battery, an audio codec (not shown), a video codec (not shown), a power amplifier (AMP), a global positioning system (GPS) device, a compass, an accelerometer (not shown), a gyroscope (not shown), a speaker, a camera, and a mass storage device (not shown) (such as hard disk drive, compact disk (CD), digital versatile disk (DVD), and so forth). Any of the integrated circuit components may be physically and electrically coupled to the board 702. In some implementations, at least one of the integrated circuit components may be a part of the processor 704.

The communication chip enables wireless communications for the transfer of data to and from the computing device. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device may include a plurality of communication chips. For instance, a first communication chip may be dedicated to shorter range wireless communications such as Wi-Fi and Bluetooth and a second communication chip may be dedicated to longer range wireless communications such as GPS, EDGE, GPRS, CDMA, WiMAX, LTE, Ev-DO, and others.

The term “processor” may refer to any device or portion of a device that processes electronic data from registers and/or memory to transform that electronic data into other electronic data that may be stored in registers and/or memory. At least one of the integrated circuit components may include an apparatus having one or more trenches extending through a portion a device structure. The device structure is embedded within a portion of a core layer of a package substrate, wherein one or more conductive interconnect structures are coupled with the one or more trenches. A thickness of the device structure is equal to a thickness of the core layer.

In various implementations, the computing device may be a laptop, a netbook, a notebook, an ultrabook, a smartphone, a tablet, a personal digital assistant (PDA), an ultra-mobile PC, a mobile phone, a desktop computer, a server, a printer, a scanner, a monitor, a set-top box, an entertainment control unit, a digital camera, a portable music player, or a digital video recorder. In further implementations, the computing device may be any other electronic device that processes data.

While certain features set forth herein have been described with reference to various implementations, this description is not intended to be construed in a limiting sense. Hence, various modifications of the implementations described herein, as well as other implementations, which are apparent to persons skilled in the art to which the present disclosure pertains are deemed to lie within the spirit and scope of the present disclosure. It is understood that the subject matter of the present description is not necessarily limited to specific applications illustrated in FIGS. 1-7. The subject matter may be applied to other integrated circuit devices and assembly applications, as well as any appropriate electronic application, as will be understood to those skilled in the art.

The following examples pertain to further embodiments and specifics in the examples may be used anywhere in one or more embodiments, where a first example is an apparatus comprising a first core layer. A first side of a prepreg material is on the first core layer and a first side of a device structure on a second side of the prepreg material. The device structure comprising: one or more trench capacitors extending partially through a thickness of the device structure. A first side of a second core layer is on the second side of the prepreg material adjacent to the device structure, wherein a second side of the device structure is coplanar with a second side of the second core layer, the second side of the second core layer opposite the first side of the second core layer.

In second examples the first example further comprises wherein a conductive layer is within each of the one or more trench capacitors.

In third examples wherein the second example comprises wherein the conductive layer comprises copper or a copper alloy.

In fourth examples wherein any of examples 1-3 further comprise wherein a first build up layer is on the second side of the device substrate and a second build up layer is on a surface of the first core layer opposite the prepreg material.

In fifth examples wherein any of examples 1˜4 further comprise wherein individual ones of the one or more trench capacitors comprise: a first conductive layer on a device substrate sidewall; a dielectric layer on the conductive layer; and a second conductive layer on the dielectric layer.

In sixth examples wherein any of examples 1-5 further comprises wherein the device structure comprises silicon.

In seventh examples wherein any of examples 1-6 further comprise wherein a conductive feature is coupled to the one or more trench capacitors and extends through a build up layer, the build up layer on the second side of the device structure.

In eighth examples wherein any of examples 1-7 further comprise wherein the device structure comprises a thickness of less than about 800 microns.

In ninth examples wherein any of examples 1-8 further comprise wherein a mold material is between a sidewall of the device structure and a sidewall of the second core layer.

In tenth examples wherein example 9 further comprises wherein the mold material comprises one or more of a standard Ajinomoto Build-Up Film (ABF), an epoxy mold materials or a photo imageable dielectric (PID) material.

In eleventh examples wherein any of examples 1-10 further comprise wherein the apparatus comprises a portion of a multilayer core structure of a package substrate.

In twelfth examples wherein example 11 further comprises a die coupled to the package substrate.

A thirteenth example is an apparatus comprising: a package substrate comprising one or more conductive interconnect structures; a device substrate comprising one or more devices, the devices extending through a portion of the device structure, wherein the device structure is embedded within a portion of a first core layer of the package substrate, and wherein the one or more conductive interconnect structures are coupled with the one or more devices; a first prepreg material on a first side of the device substrate; a second prepreg material on a second side of the device structure; and a second core layer on the second prepreg material.

In fourteenth examples wherein example 13 further comprises wherein the first side of the device structure is coplanar with a first side of the of the first core layer and a second side of the device structure is coplanar with a second side of the first core layer.

In fifteenth examples wherein any of examples 13-14 further comprise wherein an encapsulant material is between a sidewall of the device structure and a sidewall of the first core layer.

In sixteenth examples wherein any of examples 13-15 further comprise wherein the device structure comprises a first device structure, and wherein a second device structure is embedded within a portion of the second core layer.

In seventeenth examples wherein example 16 further comprises wherein top and bottom surfaces of the second device structure are coplanar with top and bottom surfaces of the second core layer.

An eighteenth example is a method comprising: forming a device structure comprising one or more trench capacitors in a portion of a device substrate; placing the device structure in a cavity of a first core layer, wherein surfaces of the first core layer are coplanar with surfaces of the device structure; placing a first side of a prepreg layer on the first core layer; and placing a second core layer on a second side of the prepreg layer.

In nineteenth examples wherein example 18 further comprises wherein the device structure comprises a first device structure, and further comprising placing a second device structure in a cavity of the second core layer, wherein surfaces of the second core layer are coplanar with surfaces of the second device structure.

In twentieth examples wherein any of examples 18-19 further comprise wherein the first core layer and the second core layer comprise portions of a package substrate, and further comprising placing a die on a surface of the package substrate, wherein the one or more trench capacitors are coupled to the die.

It will be recognized that principles of the disclosure are not limited to the embodiments so described but can be practiced with modification and alteration without departing from the scope of the appended claims. The above embodiments may include the undertaking only a subset of such features, undertaking a different order of such features, undertaking a different combination of such features, and/or undertaking additional features than those features explicitly listed. The scope of the embodiments should, therefore, be determined with reference to the appended claims, along with the full scope of equivalents to which such claims are entitled.

What is claimed is:

1. An apparatus, comprising:
a first dielectric material;
a first side of a second dielectric material on the first dielectric material;
a first side of a device structure on a second side of the second dielectric material, the device structure comprising:
one or more trench capacitors extending partially through a thickness of a device structure; and
a first side of an additional first dielectric material on the second side of the second dielectric material adjacent to the device structure, wherein a second side of the device structure is coplanar with a second side of the additional first dielectric material, the second side of the additional first dielectric material opposite the first side of the additional first dielectric material.

2. The apparatus of claim 1, wherein a conductive layer is within each of the one or more trench capacitors and wherein a copper layer is between the first dielectric material and the first side of the second dielectric material.

3. The apparatus of claim 2, wherein the conductive layer comprises copper or a copper alloy and wherein the first dielectric material comprises a first core layer, the second dielectric material comprises a prepreg material, and the additional first dielectric material comprises a second core layer.

4. The apparatus of claim 1, wherein a first build up layer is on the second side of the device structure and a second build up layer is on a surface of the first dielectric material opposite the second dielectric material.

5. The apparatus of claim 1, wherein individual ones of the one or more trench capacitors comprise:
a first conductive layer on a device structure sidewall;
a dielectric layer on the first conductive layer; and
a second conductive layer on the dielectric layer.

6. The apparatus of claim 1, wherein the device structure comprises silicon and wherein the second dielectric material comprises a woven material impregnated with resin.

7. The apparatus of claim 1, wherein a conductive feature is coupled to the one or more trench capacitors and extends through a build up layer, the build up layer on the second side of the device structure.

8. The apparatus of claim 1, wherein the device structure comprises a thickness of less than about 800 microns.

9. The apparatus of claim 1, wherein a mold material is between a sidewall of the device structure and a sidewall of the additional first dielectric material.

10. The apparatus of claim 9, wherein the mold material comprises one or more of a standard Ajinomoto Build-Up Film (ABF), an epoxy mold materials or a photo imageable dielectric (PID) material.

11. The apparatus of claim 1, wherein the apparatus comprises a portion of a multilayer core structure of a package substrate.

12. The apparatus of claim 11, further comprising a die coupled to the package substrate.

13. An apparatus, comprising:
a package substrate comprising one or more conductive interconnect structures;
a device structure comprising one or more devices, the devices extending through a portion of the device structure, wherein the device structure is embedded within a portion of a first core layer of the package substrate, and wherein the one or more conductive interconnect structures are coupled with the one or more devices;
a first prepreg material on a first side of the device structure;
a second prepreg material on a second side of the device structure; and
a second core layer on the second prepreg material.

14. The apparatus of claim 13, wherein the first side of the device structure is coplanar with a first side of the of the first core layer and a second side of the device structure is coplanar with a second side of the first core layer.

15. The apparatus of claim 13, wherein an encapsulant material is between a sidewall of the device structure and a sidewall of the first core layer.

16. The apparatus of claim 13, wherein the device structure comprises a first device structure, and wherein a second device structure is embedded within a portion of the second core layer.

17. The apparatus of claim 16, wherein top and bottom surfaces of the second device structure are coplanar with top and bottom surfaces of the second core layer.

18. A method, comprising:
forming a device structure comprising one or more trench capacitors in a portion of a device substrate;
placing the device structure in a cavity of a first core layer, wherein surfaces of the first core layer are coplanar with surfaces of the device structure;
placing a first side of a prepreg layer on the first core layer; and
placing a second core layer on a second side of the prepreg layer.

19. The method of claim 18, wherein the device structure comprises a first device structure, and further comprising placing a second device structure in a cavity of the second core layer, wherein surfaces of the second core layer are coplanar with surfaces of the second device structure.

20. The method of claim 18, wherein the first core layer and the second core layer comprise portions of a package substrate, and further comprising placing a die on a surface of the package substrate, wherein the one or more trench capacitors are coupled to the die.
